(19) United States
(12) Patent Application Publication
(10) Pub. No.: US 2020/0286967 A1
(43) Pub. Date: Sep. 10, 2020

(54) Display Device

(71) Applicant: AU OPTRONICS CORPORATION, Hsin-Chu (TW)

(72) Inventors: TING-YI KUO, Hsin-Chu (TW); KUEI-BAI CHEN, Hsin-Chu (TW)

(21) Appl. No.: 16/702,627

(22) Filed: Dec. 4, 2019

(30) Foreign Application Priority Data
Mar. 8, 2019 (TW) 108107901

(51) Int. Cl. H01L 27/32

(52) U.S. Cl. CPC H01L 27/3244; H01L 27/322; H01L 27/3216

(57) ABSTRACT

A display device is provided. The display device includes a self-emissive layer and a color filter layer. The self-emissive layer includes a plurality of self-emissive units and a plurality of first non-visible light generating units which is respectively disposed among the self-emissive units. The color filter layer is disposed on the self-emissive layer, and includes a shading matrix. The first non-visible light generating units and the shading matrix respectively have a first projection area and a second projection area on a projection plane parallel to the color filter layer. The first projection area and the second projection area at least partially overlap, and the shading matrix at least partially permits the passing through of the first non-visible light generated by the first non-visible light generating units.

### BACKGROUND OF THE INVENTION

### 1. Field of the Invention

The invention generally relates to a display device. Particularly, the invention relates to a display device which generates at least part of the non-visible light.

### 2. Description of the Prior Art

In daily life, when sunlight is shone through a window, people can still feel the warmth of the sunlight and see the true colors of the scenery outside the window. However, looking at a display device composed of electronic components, no matter how vivid the colors look, we can still recognize that it is a virtual space constructed by cold machines.

FIG. 1 is a schematic diagram of the spectrum of sunlight. As shown in FIG. 1, sunlight includes visible light and non-visible light, and the warmth of sunlight comes from non-visible light composed of mostly infrared (IR) light and a small amount of ultraviolet (UV) light. Ultraviolet light radiated from the sun is non-visible with wavelength shorter than violet light and includes frequency bands of ultraviolet A (UVA), ultraviolet B (UVB), and ultraviolet C (UVC). The ozone layer of the earth blocks 97˜99% of the ultraviolet radiation that penetrates the atmosphere, and 98.7% of UV reaching the earth is UVA. The wavelength of UVA is between 0.315˜0.4 μm; it is capable of penetrating clouds and glass into a room and inside a car, and penetrating into the dermis of the skin to cause tanning. IR is invisible light whose wavelength is longer than red light; and it can be divided into near infrared (NIR), medium infrared (MIR), and far infrared (FIR) light according to wavelength. The wavelength of NIR is approximately 0.750˜1.5 microns (μm), which is the most visible wavelength to human eyes in the infrared region of electromagnetic spectrum, and it has a higher power density and generates more heat. It causes a burning sensation when radiated to human skin and makes people feel the heat; as a result, it is used as a warmer.

The application of display devices becomes more and more diversified with the development of technology. For example, an indoor display device can be used to simulate a window. Although a display device can accurately simulate the colors in the real world and achieves the visual effect similar to a real window by utilizing various improvements in the manufacturing process and structure, it cannot achieve the realistic somatosensory effect of a real window in the multi-sensory experience. Therefore, it still needs to be improved.

### SUMMARY OF THE INVENTION

It is an object of the invention to provide a display device that simulates the heat sensation from the penetration of heat. The display device has non-visible light generating units to generate heat.

It is another object of the invention to provide a display device for generating non-visible light which allows a user to feel the heat by the penetrating non-visible light.

In an embodiment, the invention provides a display device which includes a self-emissive layer and a color filter layer. The self-emissive layer includes a plurality of self-emissive units and a plurality of first non-visible light generating units which are respectively disposed among the self-emissive units.

The color filter layer is disposed on the self-emissive layer and includes a shading matrix. The first non-visible light generating units and the shading matrix respectively have a first projection area and a second projection area on a projection plane parallel to the color filter layer, and the first projection area and the second projection area at least partially overlap. The shading matrix at least partially permits the passing through of the first non-visible light generated by the first non-visible light generating units.

In another embodiment, the invention provides a display device which includes a self-emissive layer and a color filter layer. The self-emissive layer includes a plurality of self-emissive units and a plurality of first non-visible light generating units which are respectively disposed among the self-emissive units. The color filter layer is disposed on the self-emissive layer, and includes a shading matrix. The color filter layer includes a plurality of quantum dots, and the self-emissive units are a plurality of blue micro-LEDs. The color filter layer includes a plurality of penetration zones disposed among the shading matrix which respectively correspond to part of the self-emissive units. The first non-visible light generating units and the shading matrix respectively have a first projection area and a second projection area on a projection plane parallel to the color filter layer, and the first projection area and the second projection area at least partially overlap. The shading matrix at least partially permits the passing through of the first non-visible light generated by the first non-visible light generating units.

In still another embodiment, the invention provides a display device which includes a self-emissive layer and a color filter layer. The self-emissive layer includes a plurality of self-emissive units, a plurality of first non-visible light generating units which are respectively disposed among the self-emissive units, and a plurality of second non-visible light generating units. The color filter layer is disposed on the self-emissive layer, and includes a shading matrix. The color filter layer includes a plurality of quantum dots, and the self-emissive units are a plurality of blue micro-LEDs. The color filter layer includes a plurality of penetration zones disposed among the shading matrix which respectively correspond to part of the self-emissive units, and the second non-visible light generating units are respectively disposed among the self-emissive units corresponding to the penetration zones. The first non-visible light generating units and the shading matrix respectively have a first projection area and a second projection area on a projection plane parallel to the color filter layer, and the first projection area and the second projection area at least partially overlap. The shading matrix at least partially permits the passing through of the first non-visible light generated by the first non-visible light generating units.

With the application of foregoing embodiments, the invention provides a display device which at least partially permits the passing through of non-visible light to simulate the perception of receiving heat from a light source in the real world.

### BRIEF DESCRIPTION OF THE DRAWINGS

FIG. 1 is a schematic diagram of the spectrum of sunlight;

FIG. 2 is a schematic diagram of an embodiment of a display device before simulated light sources are provided;

FIG. 3 is a schematic diagram of an embodiment of a display device;

FIG. 4 is a section view of the projections of a shading matrix and a first non-visible light generating unit of a display device;

FIG. 5 is a schematic diagram of the penetration spectrum of a shading matrix and the wavelength range of a first non-visible light of a display device;

FIG. 6 is a schematic diagram of the gate lines and data lines of a display device;

FIG. 7 is an exploded view of the data channels and strip units of a display device;

FIG. 8 is a schematic diagram of another embodiment of the display device; and

FIG. 9 is a schematic diagram of another embodiment of the display device.

### DETAILED DESCRIPTION OF THE PREFERRED EMBODIMENT

The spirit of the present disclosure will be clearly described below with drawings and detailed description. It is apparent to those skilled in the art that changes and modifications from the teaching of the present disclosure may be made without departing from the spirit and scope of the disclosure by understanding the exemplary embodiments.

The terms such as “contain”, “include”, “has” and “comprise” in the specification are open terms meaning “include but not limited to”.

It should be understood that, even though the terms such as “first”, “second”, “third” may be used to describe an element, a part, a region, a layer and/or a portion in the present specification, but these elements, parts, regions, layers and/or portions are not limited by such terms. Such terms are merely used to differentiate an element, a part, a region, a layer and/or a portion from another element, part, region, layer and/or portion. Therefore, in the following discussions, a first element, portion, region, layer or portion may be called a second element, portion, region, layer or portion, and do not depart from the teaching of the present disclosure.

In addition, relative terms such as “lower” or “bottom” and “on” or “top” may be used to describe the relationship between an element and another element in the present specification, as shown in the FIGs. It should be understood that, the purpose of using relative terms is to include the different directions of the devices not shown in the FIGs. For example, if a device in an attached FIG. is turned upside down, an element described as being “under” another element will be “on top of” that element. Therefore, a descriptive term “under” may include the meaning of both “under” and “on top of”, depending on the specific orientation of the attached FIG.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

FIG. 2 is a schematic diagram of an embodiment of a display device before simulated light sources are provided. By utilizing the color filter layer 20, the display device forms each sub-pixel 24 on the glass layer 30 with three primary color materials of red, green and blue. The display device controls the signal processing of the integrated circuit to process the strong light emitted from the self-emissive layer 10 using the color filter layer 20 to display a color image. In an embodiment, the self-emissive units 11 in the self-emissive layer 10 are white micro light emitting diodes (W Micro LEDs), and a full-color picture is obtained through the color filter layer 20. Specifically, the first sub-pixel 24a, the second sub-pixel 24b and the third sub-pixel 24c are green, blue and red sub-pixels respectively; after going through the green, blue and red sub-pixels, the white light of the self-emissive units 11 respectively obtains the first color light 60, the second color light 70, and the third color light 80, which are of the colors green, blue and red respectively. In another embodiment, the self-emissive units 11 are blue micro-light emitting diodes (B Micro LEDs), and quantum dot color filters (QD-CF) are used as the color filter layer 20 to achieve higher color gamut. Specifically, the color filter layer 20 vacates the space for the second sub-pixel 24b so that the blue light of the self-emissive units can directly penetrate and obtain the second color light 70 of blue. After going through the green sub-pixel and the red sub-pixel, the blue light of the self-emissive units respectively obtains the first color light 60 and the third color light 80, which are of the colors green and red respectively.

To prevent sub-pixels 24a-24c from mixing their colors and to enhance the color contrast of the three primary colors of red, green and blue, a shading matrix 21 above the color filter layer 20 is used for shielding the light. The shading matrix 21 is preferably black matrix (BM) pattern. Nowadays, a black resin photoresist, for example, is usually used as a material for producing the shading matrix, and the manufacturing process of the shading matrix is also the first step of manufacturing a color filter layer. Take the manufacturing process of the black resin photoresist as an example. Materials such as carbon black, inorganic pigments, and organic pigments are dispersed in resin and made into a light-shielding material; such material is then coated on a glass substrate and processed using the photolithographic etching pattern (PRP) technology to form a resin shading layer as required. The manufacturing process of the shading matrix can be completed in the steps of coating, exposure and development. To complete the manufacturing process of a color filter layer after the manufacturing process of the shading matrix, we have to sequentially complete the manufacturing process for the red, green, and blue color resist and the sputter deposition process of indium tin oxide (ITO) film, and so on. The color filter layer manufactured by the pigment dispersed method, the current manufacturing mainstream, has a higher precision as well as better lightfastness and heat resistance. After completing the manufacturing process of the shading matrix, the color filter layer is spin-coated with the colored photoresist colored in red, irradiated by ultraviolet light with a pattern mask for red color, has the unexposed portion removed with an alkaline developer to form the red pattern, and is then post-baked at 200 degree Celsius to get a drug-resistant pattern. The same process that forms the red pattern is then repeated to get green pattern and blue pattern.

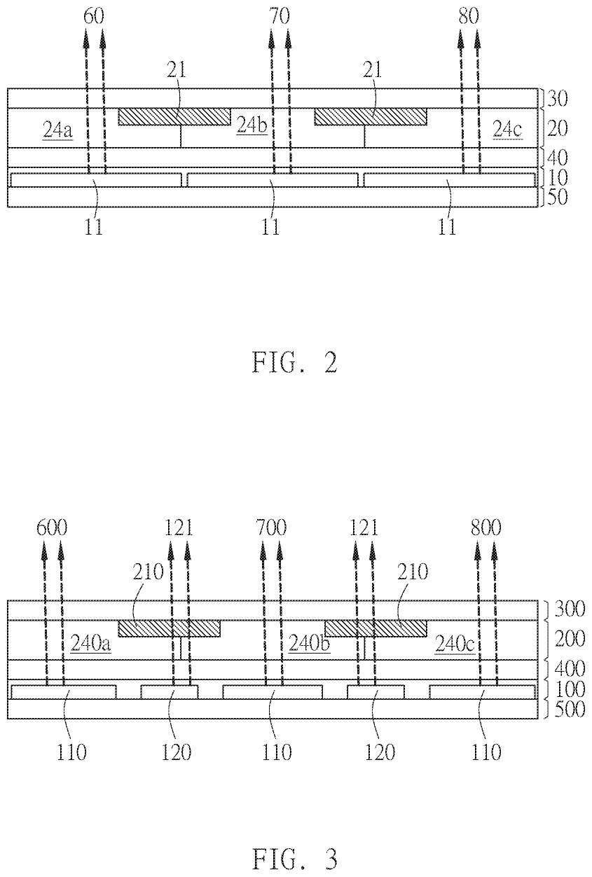

FIG. 3 is a schematic diagram of an embodiment of a display device. As shown in FIG. 3, the display device includes a glass layer 300, a color filter layer 200, a first protection layer 400, a self-emissive layer 100, and a second protection layer 500. The self-emissive layer 100 includes a plurality of self-emissive units 110 and a plurality of first non-visible light generating units 120 which are respectively disposed among the self-emissive units 110. The color filter layer 200 is disposed on the self-emissive layer 100, and includes a shading matrix 210. In an embodiment, the self-emissive units 110 are white micro-light emitting diodes (W Micro LEDs), and the first non-visible light generating units 120 are near-infrared (NIR) light generating units; in another embodiment, the self-emissive units 110 could be organic light emitting diode (OLED) units. Each sub-pixel preferably includes one or more self-illuminating units 110. The self-emissive light 111 generated by the self-illuminating units 110 penetrates the sub-pixels 240a-240c of each color on the color filter layer 200 to provide varied color lights to form a color image. The shading matrix preferably prevents color mixing of adjacent sub-pixels. In one embodiment, the first sub-pixel 240a, the second sub-pixel 240b and the third sub-pixel 240c are respectively green, blue and red sub-pixels; the self-emissive units 110 generates white light and respectively obtains the first color light 600, the second light 700 and the third color light 800, which are of the colors green, blue and red respectively by passing through the green, blue and red sub-pixels.

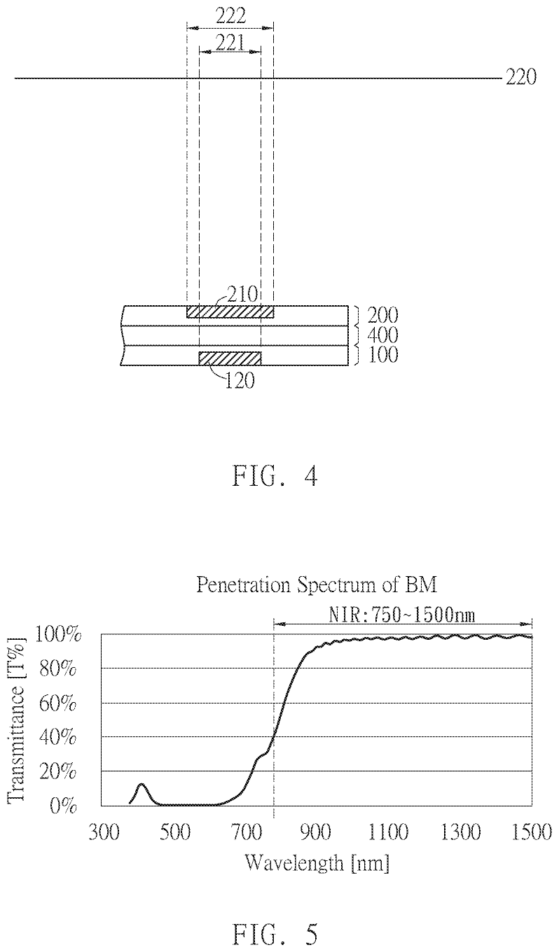

FIG. 4 is a section view of the projections of a shading matrix and a first non-visible light generating unit of a display device. As shown in FIG. 4, The first non-visible light generating unit 120 and the shading matrix 210 respectively have a first projection area 221 and a second projection area 222 on a projection plane 220 parallel to the color filter layer 200, and the first projection area 221 and the second projection area 222 at least partially overlap. In a preferred embodiment, the first projection area 221 is fully covered by the second projection area 222. In one embodiment, the projection plane 220 is a physical plane, such as a display surface. In another embodiment, the projection plane 220 is a virtual plane.

FIG. 5 is a schematic diagram of the penetration spectrum of a shading matrix and the wavelength range of a first non-visible light of a display device. In the embodiment of FIG. 5, the first non-visible light is near-infrared (NIR) light and its wavelength ranges, for example, from 750 to 1500 nanometers (nm). The penetration spectrum of the shading matrix preferably ranges from 850 to 1500 nanometers (nm); that is, at least part of the light in this band interval can pass through the shading matrix. In the embodiment of FIG. 5, the shading matrix has a transmittance of 80% or more in the wavelength ranges from 850 to 1500 nm and a transmittance of 90% or more in the wavelength ranges from 888 to 1500 nm. As shown in FIG. 5, in the above-mentioned NIR light band, the illustrated shading matrix has a transmittance of 40% to 90% in the wavelength ranges from 750 to 900 nm, and the transmittance is higher than 90% in the wavelength ranges more than 900 nm. Consequently, the shading matrix 210 in FIG. 3 at least partially permits the passing through of the first non-visible light 121 generated by the first non-visible light generating units 120. In a preferred embodiment, the first non-visible light generating units 120 are near-infrared (NIR) light generating units, and the first non-visible light 121 is near-infrared (NIR) light. In the present invention, users can feel the heat when NIR light penetrates the shading matrix 210 and spreads out. Specifically, the present invention adjusts the range of penetration spectrum by adjusting the ingredients of the shading matrix, for example, the dye ingredients, to block or reinforce light of a specific color, and consequently allowing the NIR light to penetrate the shading matrix to let the human body feel the heat.

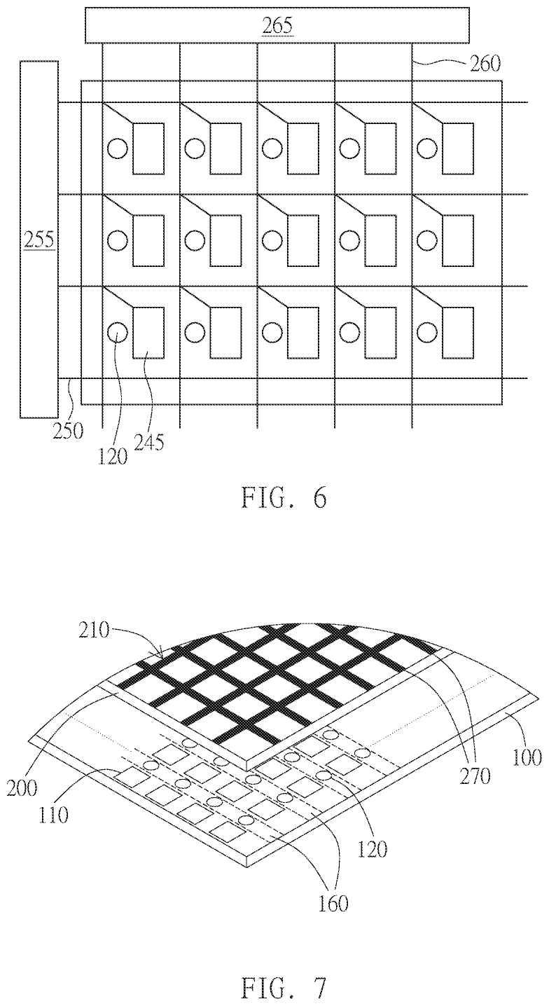

FIG. 6 is a schematic diagram of the gate lines and data lines of a display device. As shown in FIG. 6, the matrix structure comprised of a plurality of pixel electrodes 245 in the display device has a plurality of gate lines 250, the transverse wires, connected to a gate driver 255, as well as a plurality of data lines 260, the vertical wires, connected to a data driver 265. The first non-visible light generating units 265 may be disposed in the spaces adjacent to each pixel electrode 245 on the gate line side or the data line side. The former is parallel to the gate lines and is located between two gate lines; the latter is parallel to the data lines and is located between two data lines. In one embodiment, the space in the longitudinal cross section of the disposed data lines is wider, owing to less metal wiring or component; as a result, a preferred embodiment would dispose the first non-visible light generating unit 120 on the data line side. However, in another embodiment, it is also possible to dispose the first non-visible light generating units 120 on both the gate line side and the data line side.

FIG. 7 is an exploded view of the data channels and strip units of a display device. As shown in FIG. 7, the self-emissive layer 100 has a plurality of data channels 160 respectively formed among the self-emissive units 110, and the first non-visible light generating units 120 are respectively located within the data channels 160. The shading matrix 210 comprises a plurality of strip units 270 arranged side by side, and the strip units 270 extend along the data channels 160 respectively. In an embodiment, the strip units 270 are the strip shielding layer, the shading matrix 210 disposed on the self-emissive layer 200 in the direction of the data channels 160, for shielding the color light generated by the self-emissive units 110 of the self-emissive layer 200, and are penetrated by the first non-visible light generated by the first non-visible light generating units 120 on the data channels 160 to make users feel the heat. In a preferred embodiment, the self-emissive units 110 are white micro-light emitting diodes (W Micro LEDs) units. In another embodiment, the self-emissive units 110 are organic light emitting diode (OLED) units.

FIG. 8 is a schematic diagram of another embodiment of the display device. The difference between the embodiment of FIG. 8 and that of FIG. 3 is, the self-emissive units in FIG. 8 are a plurality of blue light self-emissive units that go with the quantum dot color filters (QDCF) of the color filter layer 200′. As shown in FIG. 8, the self-emissive layer 100′ includes a plurality of self-emissive units 110′, and the color filter layer 200′ has a plurality of penetration zones 230′ disposed among the shading matrix 210′ and respectively correspond to part of the self-emissive units 110′. The self-emissive light generated by the self-emissive units 110′ penetrates the sub-pixels 240′ or the penetration zones 230′ on the color filter layer 200′ to provide varied color lights to form a color image. In a preferred embodiment, the self-emissive units are blue micro-light emitting diodes (B Micro LEDs) units. In another embodiment, the self-emissive units are blue organic light emitting diode (B OLED) units.

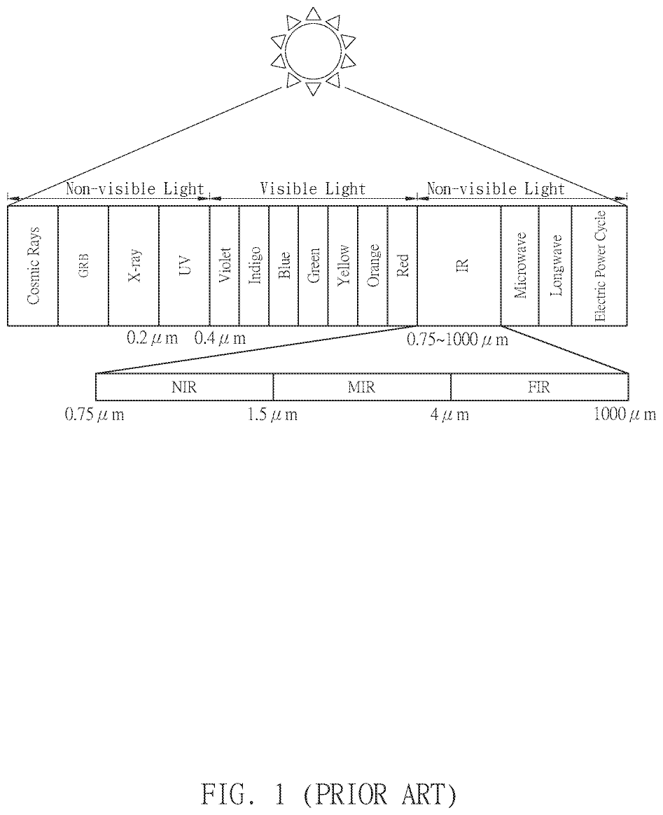

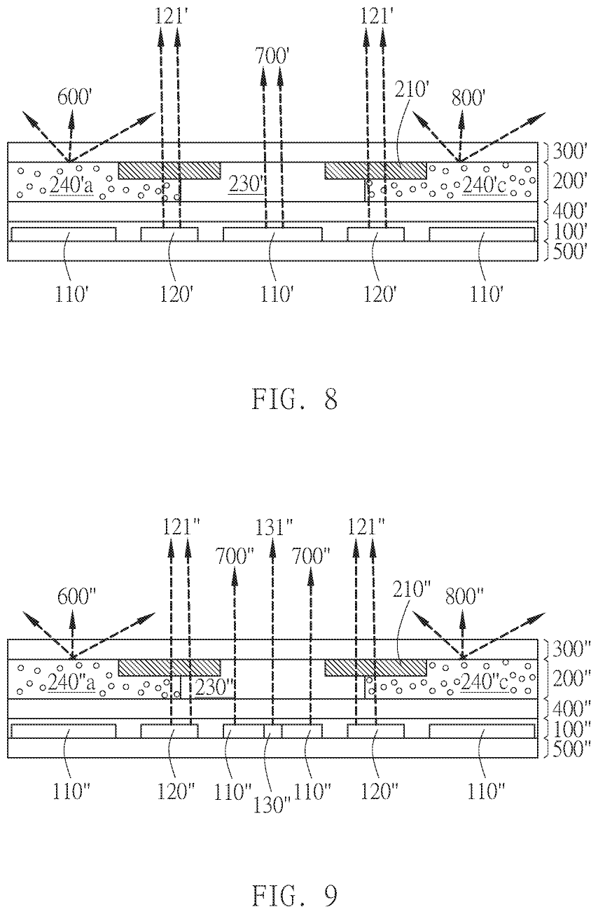

FIG. 9 is a schematic diagram of another embodiment of the display device. The difference between the embodiment of FIG. 9 and that of FIG. 8 is, a plurality of second non-visible light generating units 130″ are added to the self-emissive layer 100″ in FIG. 9 to increase the somatosensory heat sources. As shown in FIG. 9, the self-emissive layer 100″ includes a plurality of self-emissive units 110″; the color filter layer 200″ has a plurality of penetration zones 230″ disposed among the shading matrix 210″ and respectively correspond to part of the self-emissive units 110″. The self-emissive light generated by the self-emissive units 110″ penetrates the sub-pixels 240″ or the penetration zones 230″ on the color filter layer 200″ to provide varied color lights to form a color image. In a preferred embodiment, the first non-visible light 121″ is near-infrared (NIR) light, and the second non-visible light 131″ is ultraviolet (UV) light. As shown in FIG. 1, the wavelength of the emission spectrum of NIR light and UV light are respectively located at a different end of a visible wavelength range. It further changes user's perceptions towards lights or increases user's somatosensory temperature with the second non-visible light generating units. In addition, the nature of light provided by the second non-visible light generating units may differ from the nature of light provided by the first non-visible light generating units to provide varied applications and changes, but not limited thereto.

Although the preferred embodiments of present invention have been described herein, the above description is merely illustrative. The preferred embodiments disclosed will not limit the scope of the present invention. Further modification of the invention herein disclosed is possible for those skilled in the respective arts and all such modifications are deemed to be within the scope of the invention as defined by the appended claims.

What is claimed is:

1. A display device, comprising:
a self-emissive layer, comprising:
a plurality of self-emissive units; and
a plurality of first non-visible light generating units respectively disposed among the self-emissive units; and
a color filter layer disposed on the self-emissive layer and comprising a shading matrix; wherein
the first non-visible light generating units and the shading matrix respectively have a first projection area and a second projection area on a projection plane parallel to the color filter layer;
the first projection area and the second projection area at least partially overlap; and
the shading matrix at least partially permits the passing through of the first non-visible light generated by the first non-visible light generating units.

2. The display device according to claim 1, wherein
each of the first non-visible light generating units has a first non-visible emission spectrum; and
the shading matrix has a penetration spectrum; wherein
the first non-visible emission spectrum and the penetration spectrum at least partially overlap.

3. The display device according to claim 2, wherein
the penetration spectrum ranges from 850 to 1500 nm.

4. The display device according to claim 1, wherein
the self-emissive layer has a plurality of data channels respectively formed among the self-emissive units;
the first non-visible light generating units are respectively located within the data channels;
the shading matrix comprises a plurality of strip units arranged side by side; and
the strip units extend along the data channels respectively.

5. The display device according to claim 1, wherein
light generated by the first non-visible light generating units is near infrared.

6. The display device according to claim 1, wherein
the color filter layer has a plurality of quantum dots; and
the self-emissive units are a plurality of blue micro-LEDs.

7. The display device according to claim 6, wherein
the color filter layer has a plurality of penetration zones disposed among the shading matrix and respectively correspond to part of the self-emissive units.

8. The display device according to claim 6, wherein
the self-emissive layer comprises a plurality of second non-visible light generating units; wherein
the color filter layer has a plurality of penetration zones disposed among the shading matrix and respectively correspond to part of the self-emissive units; and
the second non-visible light generating units are respectively disposed within the self-emissive units corresponding to the penetration zones.

9. The display device according to claim 8, wherein
each of the second non-visible light generating units has a second non-visible emission spectrum; and
each of the first non-visible light generating units has a first non-visible emission spectrum; wherein
the wavelength of the second non-visible emission spectrum and the wavelength of the first non-visible emission spectrum are respectively located at a different end of a visible wavelength range.

10. The display device according to claim 8, wherein
the second non-visible light generating units generates a plurality of ultraviolet.
